(19) United States
(12) Patent Application Publication
(10) Pub. No.: US 2026/0144116 A1
(43) Pub. Date: May 21, 2026

(54) SEMICONDUCTOR PACKAGE INCLUDING SUBSTRATE

(71) Applicant: Samsung Electronics Co., Ltd., Suwon-si (KR)

(72) Inventors: Pilsung Choi, Suwon-si (KR); Jiwon Kang, Suwon-si (KR); Hyeon Hwang, Suwon-si (KR)

(21) Appl. No.: 19/348,402

(22) Filed: Oct. 2, 2025

(30) Foreign Application Priority Data
Nov. 15, 2024 (KR) 10-2024-0163226

(51) Int. Cl. H01L 23/498; H01L 23/28; H01L 23/00

(52) U.S. Cl. CPC H10W 70/685; H10W 74/00; H10W 90/701; H10W 72/884; H10W 90/734; H10W 90/754

(57) ABSTRACT

A semiconductor package includes a substrate including an insulating layer and an interconnection layer disposed on the insulating layer, the interconnection layer formed of conductive patterns, the substrate having a lower surface on which lower pads are disposed, a lower protective layer disposed on the lower surface of the substrate and having lower openings exposing the lower pads, a semiconductor chip disposed on an upper surface of the substrate, an encapsulant covering the semiconductor chip, and connection bumps disposed below the lower protective layer. The lower openings include first lower openings and second lower openings surrounding the first lower openings, the lower pads are respectively disposed within the first lower openings and lower patterns are respectively disposed within the second lower openings, and the connection bumps are electrically connected to the lower pads within the first lower openings, respectively.

### CROSS-REFERENCE TO RELATED APPLICATION(S)

This application claims benefit of priority under 35 USC § 119 to Korean Patent Application No. 10-2024-0163226 filed on November 15, 2024 in the Korean Intellectual Property Office, the disclosure of which is incorporated herein by reference in its entirety.

### BACKGROUND

The present inventive concept relates to a semiconductor package.

As electronic devices have become lighter and have been implemented with higher performance, the development of miniaturized and high-performance semiconductor chips has been required. As the pitch thereof has become finer, a gap between various elements in semiconductor packages has reduced, thereby causing various problems.

### SUMMARY

An aspect of the present inventive concept provides a semiconductor package with improved reliability.

According to an aspect of the present inventive concept, a semiconductor package includes: a substrate including an insulating layer and an interconnection layer disposed on the insulating layer, the interconnection layer formed of conductive patterns, the substrate having a lower surface on which lower pads are disposed and an upper surface on which upper pads are disposed; an upper protective layer disposed on the upper surface of the substrate and having upper openings exposing respective portions of the upper pads; a lower protective layer disposed on the lower surface of the substrate and having lower openings exposing respective portions of the lower pads; a semiconductor chip disposed on the upper protective layer and including connection pads electrically connected to at least a portion of the upper pads through the upper openings; an encapsulant covering at least a portion of each of the upper protective layer and the semiconductor chip on the upper protective layer; and connection bumps disposed below the lower protective layer, wherein the lower openings include first lower openings and second lower openings surrounding at least a portion of each of the first lower openings, the lower pads are respectively disposed within the first lower openings and lower patterns are disposed within the second lower openings, and the connection bumps are electrically connected to the lower pads within the first lower openings, respectively.

According to an aspect of the present inventive concept, a semiconductor package includes: a substrate including an insulating layer and an interconnection layer, disposed on the insulating layer, and having a lower surface on which a lower pad is disposed and an upper surface on which an upper pad is disposed; a lower protective layer covering a portion of the lower pad below the lower surface of the substrate; an upper protective layer covering a portion of the upper pad on the upper surface of the substrate; a semiconductor chip disposed on the substrate and electrically connected to at least a portion of the upper pad through central openings; an encapsulant encapsulating at least a portion of the semiconductor chip on the substrate; and connection bumps electrically connected to the lower pad below the lower protective layer, wherein at least one of the upper protective layer and the lower protective layer includes central openings exposing at least a portion of the upper pad or the lower pad and outer openings surrounding at least a portion of a circumference of each of the central openings.

According to an aspect of the present inventive concept, a semiconductor package includes: a substrate including an insulating layer and an interconnection layer disposed on the insulating layer, the substrate having a lower surface on which a lower pad is disposed; a lower protective layer covering a portion of the lower pad and a portion of the lower surface of the substrate; a semiconductor chip disposed on the substrate and electrically connected to the interconnection layer; an encapsulant encapsulating the semiconductor chip on the substrate; and connection bumps electrically connected to the lower pad, the connection bumps overlapping the lower protective layer in a horizontal direction, wherein the lower protective layer has a plurality of first openings and a plurality of second openings respectively surrounding at least portions of the plurality of first openings, each of the plurality of first openings forms a group with at least one second opening adjacent to the corresponding first opening to form a plurality groups of openings, and a gap between a first opening and a second opening in a first group among the plurality of groups is smaller than a gap between the second opening in the first group and a second opening in a second group among the plurality of groups.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a cross-sectional view illustrating a semiconductor package according to an embodiment of the present inventive concept;

FIG. 2A to FIG. 2C are plan views illustrating embodiments of lower patterns applicable to the semiconductor package of FIG. 1;

FIG. 3 is a cross-sectional view illustrating a semiconductor package according to an embodiment of the present inventive concept;

FIG. 4 is a cross-sectional view illustrating a semiconductor package according to an embodiment of the present inventive concept;

FIG. 5 is a cross-sectional view illustrating a semiconductor package according to an embodiment of the present inventive concept; and

FIG. 6A to FIG. 6G are cross-sectional views schematically illustrating a method of manufacturing a semiconductor package according to an embodiment of the present inventive concept.

### DETAILED DESCRIPTION

Hereinafter, embodiments of the present inventive concept will be described with reference to the accompanying drawings. Unless otherwise specifically stated, in this specification, terms, such as ‘upper,’ ‘upper surface’, ‘lower,’ ‘lower surface,’ and ‘side surface’ are based on the drawings and may actually vary depending on a direction in which the components are arranged. For example, spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Various pads described herein may be conductive terminals connected to internal wiring of a device (e.g., chip/substrate), and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may have a planar surface having dimensions greater than wiring (e.g., X-Y horizontal dimensions of a pad are both greater than the width of an internal wiring to which it is connected) to promote an electrical connection to a further terminal, such as a bump or solder ball, and/or an external wiring.

Throughout the specification, when a component is described as "including" a particular element or group of elements, it is to be understood that the component is formed of only the element or the group of elements, or the element or group of elements may be combined with additional elements to form the component, unless the context clearly and/or explicitly describes the contrary.

It will be understood that when an element is referred to as being "connected" or "coupled" to or “on” another element, it can be directly connected or coupled to or on the other element or intervening elements may be present. In contrast, when an element is referred to as being "directly connected" or "directly coupled" to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

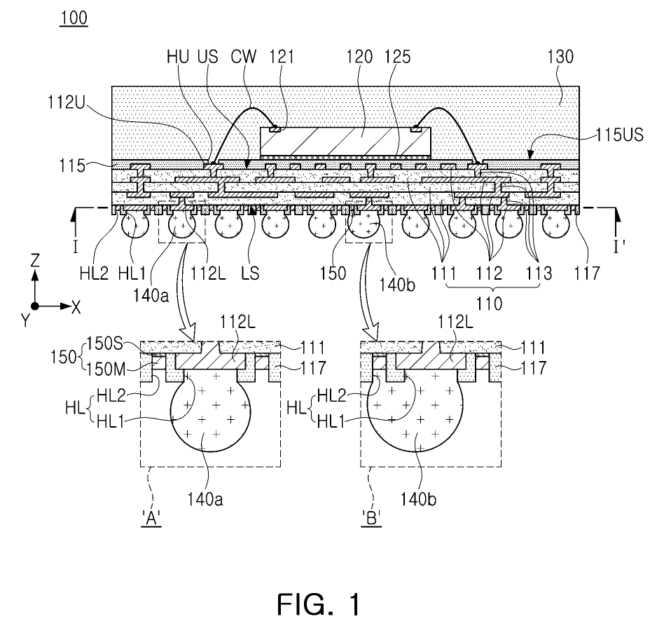

FIG. 1 is a cross-sectional view illustrating a semiconductor package 100 according to an embodiment of the present inventive concept.

Referring to FIGS. 1A and 1B, the semiconductor package 100 of an embodiment may include a substrate 110, an upper protective layer 115, a lower protective layer 117, a semiconductor chip 120, an encapsulant 130, and connection bumps 140 (140a, 140b …).

The substrate 110 may be a support substrate on which the semiconductor chip 120 is mounted, and may be a package substrate for redistributing connection pads 121 of the semiconductor chip 120. The package substrate may include or may be a printed circuit board (PCB), a ceramic substrate, a glass substrate, a tape interconnection board, etc. For example, the substrate 110 may have a lower surface LS and an upper surface US opposite each other and may include an insulating layer 111, an interconnection layer 112, and an interconnection via 113.

The insulating layer 111 may include an insulating material. For example, the insulating material may include or may be a thermosetting resin, such as an epoxy resin, a thermoplastic resin, such as polyimide, or a resin obtained by impregnating an inorganic filler or/and glass fiber (glass cloth, glass fabric) with the thermosetting resin or the thermoplastic resin, for example, prepreg, Ajinomoto buildup film (ABF), flame retardant (FR-4), bismaleimide triazine (BT), or photo-imageable dielectric (PID). For example, the insulating layer 111 may include a non-photosensitive resin, such as prepreg, ABF, or a photosensitive resin, such as PID.

The substrate 110 may include a plurality of insulating layers 111 stacked in a vertical direction (a Z-axis direction). The uppermost insulating layer 111 among the plurality of insulating layers 111 may provide an upper surface US of the substrate 110, and the lowest insulating layer 111 may provide a lower surface LS of the substrate 110. Depending on the process, the boundary between the plurality of insulating layers 111 may not be apparent. Depending on an embodiment, a smaller or larger number of insulating layers 111 may be formed in the substrate 110 than those illustrated in the drawings. When the substrate 110 is a printed circuit board, a core layer located in the middle of the plurality of insulating layers 111 may be thicker than the insulating layers 111 stacked thereabove and/or therebelow. The core layer may be formed using, for example, a copper clad laminate (CCL), an unclad copper clad laminate (unclad CCL), a glass substrate, or a ceramic substrate. However, the present inventive concept is not limited thereto, and the substrate 110 may be a printed circuit board not including a core layer.

The interconnection layer 112 may include, for example, a metal material including copper (Cu), aluminum (Al), silver (Ag), tin (Sn), gold (Au), nickel (Ni), lead (Pb), titanium (Ti), or alloys thereof. The interconnection layer 112 may include, for example, a ground pattern, a power pattern, and a signal pattern. The signal pattern may provide a path for transmitting/receiving various signals, such as data signals, excluding ground voltages and power voltages, and the ground pattern and the power pattern may transmit/receive a ground voltage and a power voltage, respectively. For example, the interconnection layer 112 may be formed of conductive patterns.

The substrate 110 may include a plurality of interconnection layers 112 respectively arranged on the plurality of insulating layers 111. The plurality of interconnection layers 112 may be electrically connected to each other through interconnection vias 113. For example, the interconnection vias 113 may be formed of conductive material. The number of the interconnection layers 112 may be determined according to the number of the insulating layers 111 and may include more or fewer layers than those illustrated in the drawings. The interconnection layers 112 located at the lowermost and uppermost positions among the plurality of interconnection layers 112 may include pads 112P on which the semiconductor chip 120 and the connection bumps 140 are mounted/connected. The pads 112P may include lower pads 112L and upper pads 112U and may be formed to have different sizes and/or pitches depending on a target/device mounted/connected thereon. For example, the lower pads 112L disposed on the lower surface LS of the substrate 110, e.g., on a lower surface of the lowermost interconnection layer 112 may have a larger size and/or pitch than those of the upper pads 112U disposed on the upper surface US of the substrate 110, e.g., on an upper surface of the uppermost interconnection layer 112.

The interconnection via 113 is electrically connected to the interconnection layer 112 and may include a signal via, a ground via, and a power via, e.g., transmitting data signal, ground voltage, and power voltage, respectively. The interconnection via 113 may include a metal material including, for example, copper (Cu), aluminum (Al), silver (Ag), tin (Sn), gold (Au), nickel (Ni), lead (Pb), titanium (Ti), or alloys thereof. The interconnection via 113 may have a filled via formed by filling the inside of a via hole with a metal material or a conformal via in which a metal material is formed along an inner wall of the via hole. The interconnection via 113 may be in a form integral with the interconnection layer 112, e.g., as one body without a boundary between the interconnection via 113 and the interconnection layer 112, but the inventive concept is not limited thereto.

The upper protective layer 115 is disposed on the upper surface US of the substrate 110 to cover at least a portion of an upper pad 112U and may have upper openings HU exposing at least a portion of the upper pad 112U. The upper protective layer 115 may be a solder resist layer protecting the interconnection layer 112 from external physical/chemical damage. The solder resist layer may include an insulating material, and may be formed of/using, for example, prepreg, ABF, FR-4, BT, or photo solder resist (PSR).

The lower protective layer 117 may be disposed on the lower surface LS of the substrate 110 to cover and/or vertically overlap at least a portion of each of the lower pads 112L and may have lower openings HL exposing at least a portion of each of the lower pads 112L. The lower protective layer 117 may be a solder resist layer protecting the lower pads 112L from external physical/chemical damage similarly to the upper protective layer 115. The lower protective layer 117 may include an insulating material the same as or similar to the upper protective layer 115.

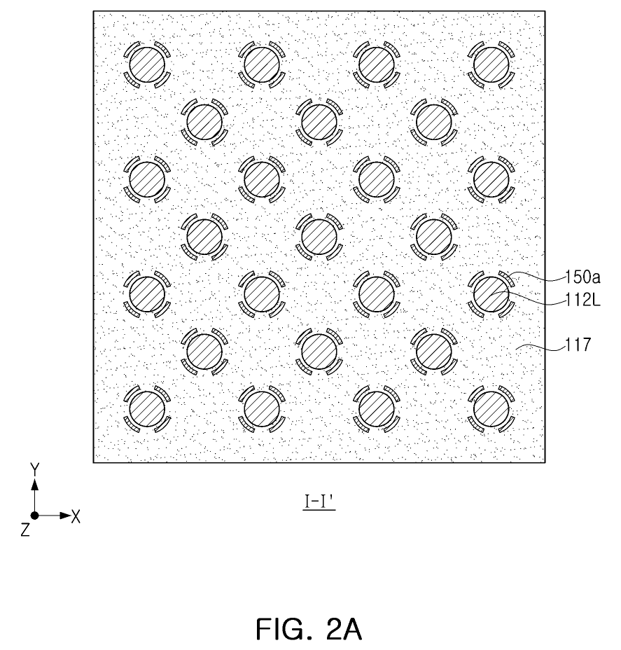

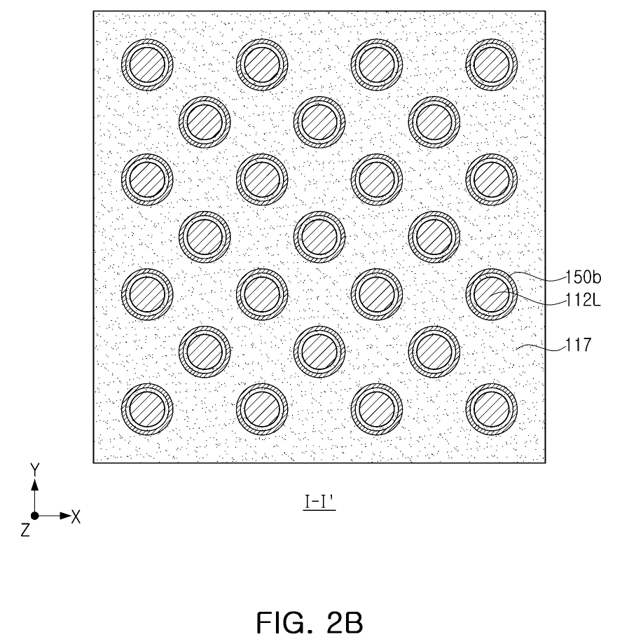

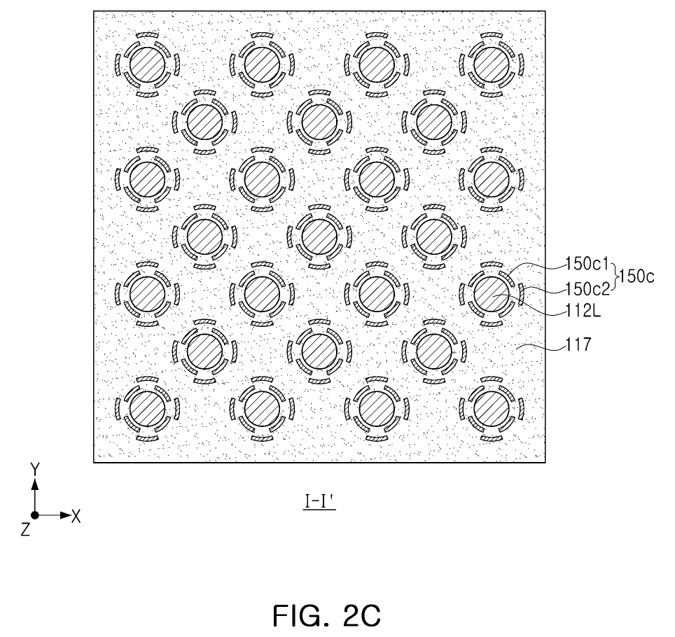

Referring to FIG. 2A together with FIG. 1, the lower openings HL may include first lower openings HL1 and second lower openings HL2 surrounding at least a portion of each of the first lower openings HL1. A width of the first lower opening HL1 in a horizontal direction may be smaller than a width of a lower pad 112L in the horizontal direction, but is not limited thereto. The second lower openings HL2 may have a structure surrounding the outer side of the first lower openings HL1 and may include a plurality of divided portions. The first lower openings HL1 may be arranged in a zigzag shape, but are not limited thereto. For example, a line connecting center points of two closest first lower openings HL1 may have an angle of 45º with respect to a side of the substrate 110 in a plan view. The second lower openings HL2 may be arranged between the adjacent first lower openings HL1. The first lower openings HL1 may be referred to as central/inner openings or lower central/inner openings, and the second lower openings HL2 may be referred to as outer openings or lower outer openings. Each of the plurality of first lower openings HL1 forms a group with at least one second lower opening HL2 adjacent to a corresponding one of the plurality of first lower openings HL1 among the plurality of second lower openings HL2, and the lower protective layer 117 may include a plurality of groups including at least first and second groups, and an interval/distance between the first opening HL1 and the second lower opening HL2 in the first group may be smaller than an interval/distance between the second lower opening HL2 of the first group and the second lower opening HL2 of the second group.

The lowermost interconnection layer 112 may include a lower pad 112L formed on a lowermost layer of the insulating layers 111 within each of the first lower openings HL1 and a lower pattern 150 may be formed on the lowermost layer of the insulating layers 111 within each of the second lower openings HL2. The lower pad 112L is electrically connected to the connection bumps 140 as a part of the interconnection layer 112 and may electrically connect the semiconductor package 100 to an external device. The lower pattern 150 does not contact the interconnection layer 112, may have a structure spaced apart from each other, and may be a dummy pattern electrically insulated from the interconnection layer 112. The lower pattern 150 may include a seed layer 150S and a metal layer 150M on the seed layer 150S. The metal layer 150M of the lower pattern 150 may include the same material as that of the lower pad 112L, and may include, for example, copper (Cu).

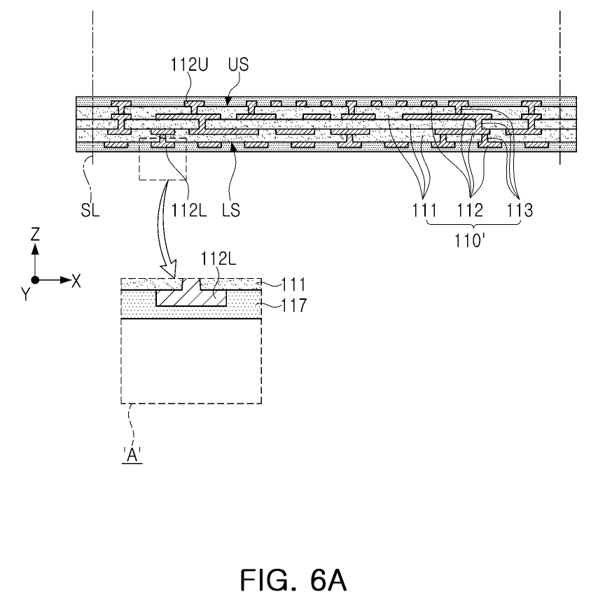

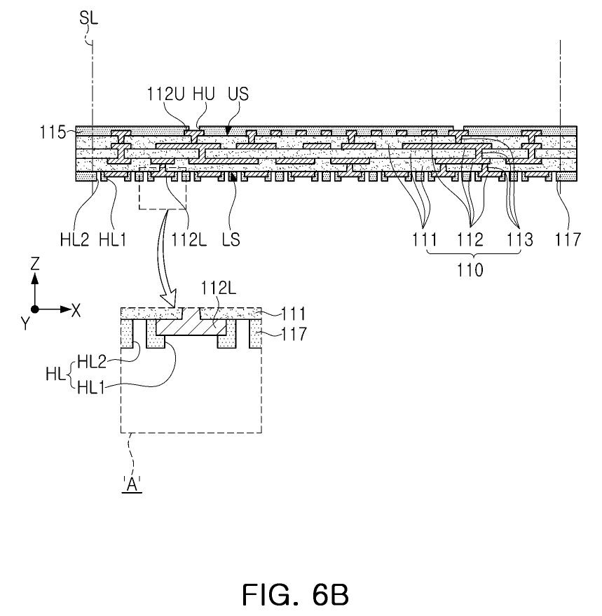

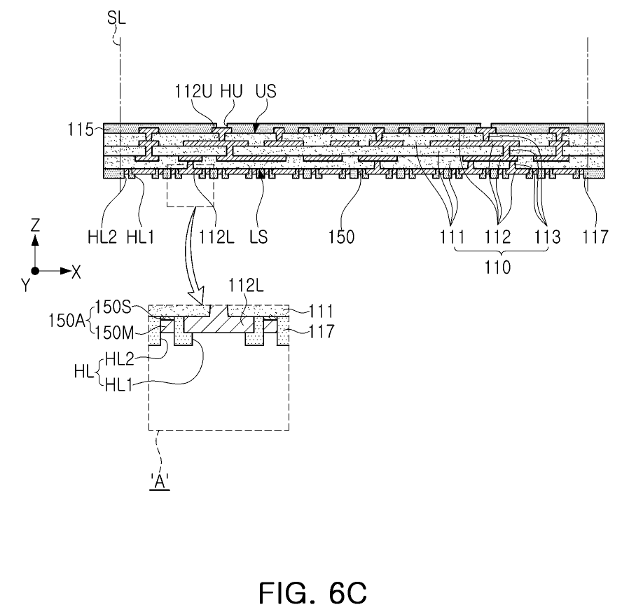

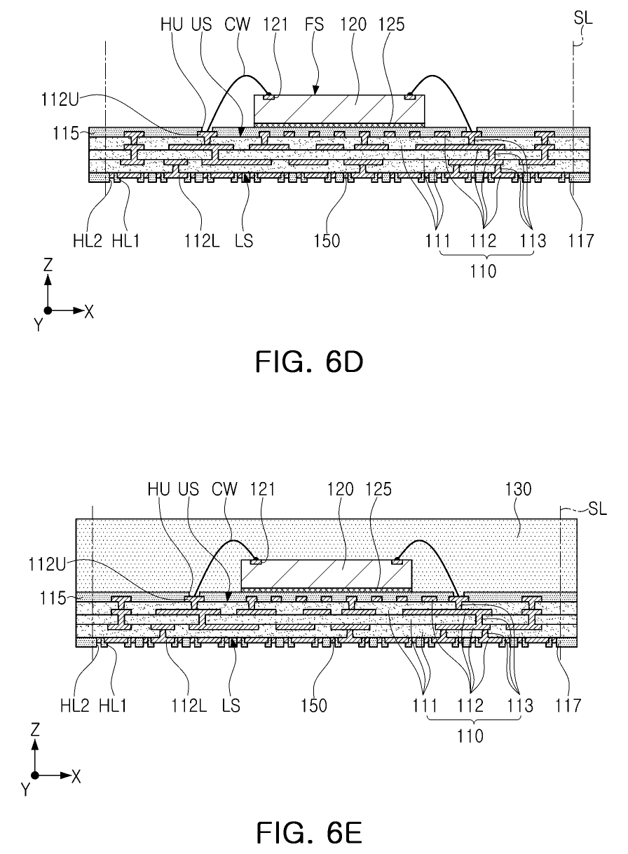

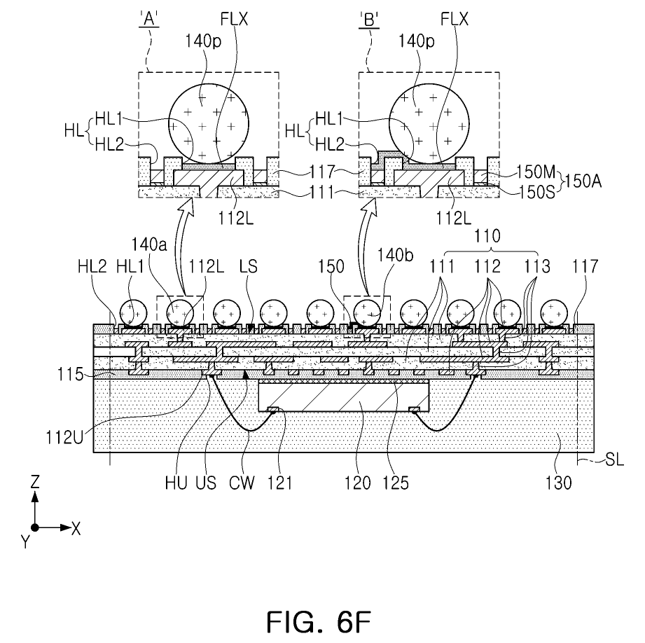

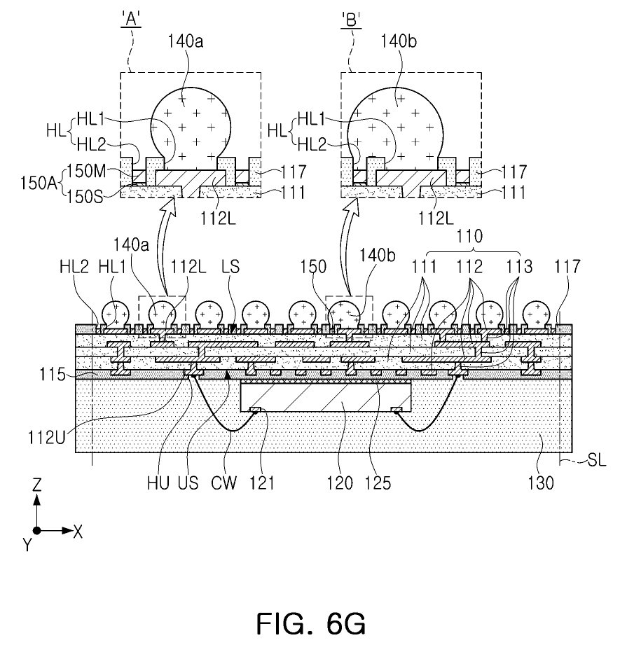

The second lower opening HL2 of the semiconductor package 100 of the present embodiment may surround at least a portion of the circumference of the first lower opening HL1 exposing at least a portion of the lower pad 112L, and the lower pattern 150 may fill at least a portion within the second lower opening HL2. The lower pattern 150 may align a flux (FLX; see FIG. 6F) and a preliminary connection bump (140p; see FIG. 6F) in a specific position (e.g., on the lower pad 112L) in the process of forming the connection bump 140 thereafter, perform a reflow process, and prevent the connection bump 140 from contacting an adjacent connection bump 140.

The semiconductor chip 120 may be disposed on the upper protective layer 115 and may include connection pads 121 electrically connected to the interconnection layer 112. The semiconductor chip 120 may be electrically connected to at least some of the upper pads 112U through upper openings HU of the upper protective layer 115. The semiconductor chip 120 may include silicon (Si), germanium (Ge), or gallium arsenide (GaAs), and may be various types of integrated circuits. The integrated circuit may be a processor chip, such as a central processor (e.g., CPU), a graphics processor (e.g., GPU), a field programmable gate array (FPGA), an application processor (AP), a digital signal processor, an encryption processor, a microprocessor, a microcontroller, etc., but is not limited thereto, and may also be a logic chip, such as an analog-to-digital converter or an application-specific IC (ASIC), or a memory chip, such as a volatile memory (e.g., DRAM), a non-volatile memory (e.g., ROM and flash memory). Each of the connection pads 121 may be a pad of a bare chip (e.g., an aluminum (Al) pad), but may also be a pad of a packaged chip (e.g., a copper (Cu) pad) according to an embodiment.

The semiconductor chip 120 may be mounted on the substrate 110 using a wire-bonding method. For example, the upper protective layer 115 may have an upper surface 115US contacting the encapsulant 130, and the semiconductor chip 120 may have a rear surface facing the upper surface 115US of the upper protective layer 115 and a front surface opposite to the rear surface and having connection pads 121 arranged thereon. An adhesive layer 125 may be disposed between the rear surface of the semiconductor chip 120 and the upper surface 115US of the upper protective layer 115. The connection pads 121 of the semiconductor chip 120 may be electrically connected to the interconnection layer 112 via a conductive wire CW. The conductive wire CW may include gold (Au), silver (Ag), lead (Pb), aluminum (Al), copper (Cu), or alloys thereof.

The number of semiconductor chips 120 is not limited to one as illustrated in FIG. 1, and according to an embodiment, the semiconductor package 100 may include a plurality of semiconductor chips arranged horizontally (in the X- or Y-direction) and/or vertically (in the Z direction).

The encapsulant 130 may encapsulate at least a portion of each of the semiconductor chips 120 (for example, the encapsulant 130 may encapsulate side surfaces and upper surfaces of the semiconductor chips 120) and the conductive wire CW on the upper protective layer 115. The encapsulant 130 may include, for example, a thermosetting resin, such as an epoxy resin, a thermoplastic resin, such as polyimide, or a prepreg, ABF, FR-4, BT, EMC (Epoxy Molding Compound) including an inorganic filler or/and glass fiber.

The connection bumps 140 are arranged on the lower surface LS of the substrate 110 and may be electrically connected to the lower pads 112L. The connection bumps 140 may be respectively arranged in the first lower openings HL1 of the lower protective layer 117. The connection bumps 140 may physically and/or electrically connect the semiconductor package 100 to an external device. The connection bumps 140 may include a conductive material and may have a ball, pin/pillar, or lead shape. For example, the connection bumps 140 may be solder balls.

The connection bumps 140a may be electrically connected to and/or contact the lower pads 112L within the first lower openings HL1 (see ‘A’ of FIG. 1), respectively, and according to an embodiment, some connection bumps 140b among the connection bumps 140 may fill the second lower openings HL2 and may contact at least a portion of the lower pattern 150 (see ‘B’ of FIG. 1).

FIGS. 2A to 2C are plan views illustrating embodiments of the lower pattern 150 applicable to the semiconductor package 100 of FIG. 1. Each of FIGS. 2A to 2C corresponds to a drawing taken along the cross-section I-I’ of FIG. 1.

Referring to FIG. 2A, a lower pattern 150a may include a plurality of divided sub-lower patterns and may have a structure in which four sub-lower patterns surround a circumference of one lower pad 112L. At least one sub-lower pattern may be disposed between the most adjacent lower pads 112L.

Referring to FIG. 2B, a lower pattern 150b may include or may be a ring-shaped lower pattern 150b and may have a structure in which, in a plan view, one ring-shaped lower pattern 150b surrounds a circumference of one lower pad 112L. The lower pattern 150b may be arranged between the most adjacent lower pads 112L.

Referring to FIG. 2C, the lower pattern 150c may include a plurality of divided sub-lower patterns and may have a structure in which four inner patterns 150c1 surround a circumference of one lower pad 112L and four outer patterns 150c2 surround a circumference of the one lower pad 112L outside the inner patterns 150c1. At least one sub-lower pattern 150c (inner/outer pattern) may be disposed between the most adjacent lower pads 112L.

The lower pad 112L and the lower pattern 150 described above with reference to FIGS. 2A to 2C represent embodiments, and the shapes of the lower pad 112L and the lower pattern 150 applicable to the semiconductor package according to the present inventive concept are not limited thereto.

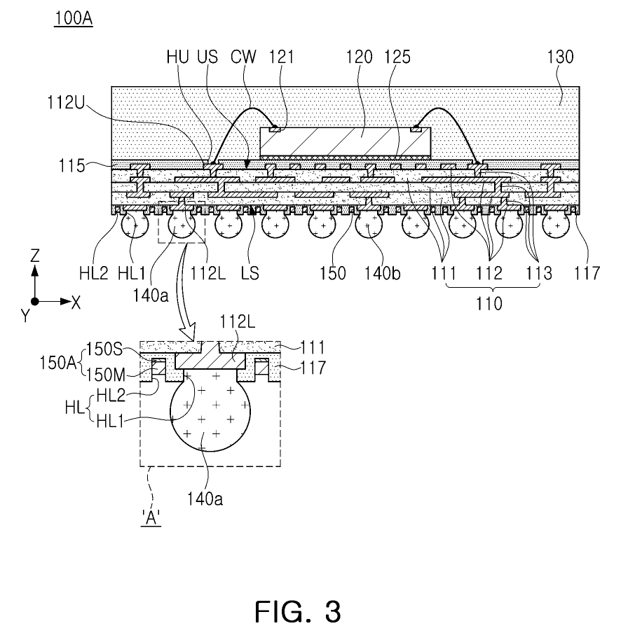

FIG. 3 is a cross-sectional view illustrating a semiconductor package 100A according to an embodiment of the present inventive concept.

Referring to FIG. 3, the semiconductor package 100A of an embodiment may have the same features as or similar features to those described above with reference to FIGS. 1 to 2C, except that an upper surface of a lower pattern 150A is located on a lower level than the upper surface of the lower pad 112L. The lower openings HL may include a first lower opening HL1 and a second lower opening HL2 surrounding the first lower opening HL1. An upper surface/end of the second lower opening HL2 may be located at a lower level than the upper surface of the lower protective layer 117, and the upper surface/end of the second lower opening HL2 may be formed of a portion of the lower protective layer 117, rather than the lower surface of the insulating layer 111. For example, the upper end of the second lower opening may be in the middle of the lower protective layer 117. In certain embodiments, a depth of the outer opening HL2 may be greater than a depth of the central opening HL1. The lower pattern 150A may fill the second lower opening HL2. For example, a seed layer 150S and a metal layer 150M of the lower pattern 150A may be sequentially disposed within the second lower opening HL2, and an upper surface of the seed layer 150S may be in contact with at least a portion of the lower protective layer 117.

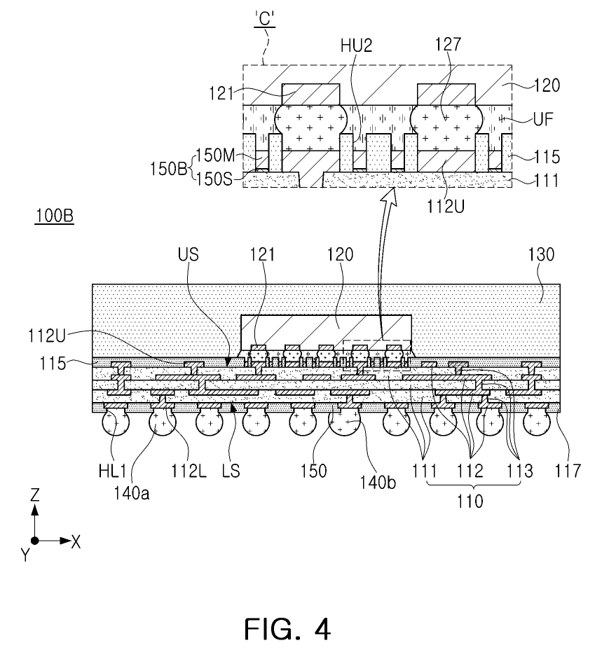

FIG. 4 is a cross-sectional view illustrating a semiconductor package 100B according to an embodiment of the present inventive concept.

Referring to FIG. 4, a semiconductor package 100B of an embodiment may have the same features as or similar features to those described above with reference to FIGS. 1 to 3, except that the uppermost interconnection layer 112 has an upper pattern 150B and the upper protective layer 115 includes a plurality of second upper openings HU2, e.g., each surrounding a corresponding one of the upper openings HU. The semiconductor package 100B may include conductive bumps 127 electrically connecting connection pads 121 of the semiconductor chip 120 to at least some of the upper pads 112U below the semiconductor chip 120 and an underfill portion UF surrounding at least a portion of each of the conductive bumps 127 below the semiconductor chip 120. The underfill portion UF may cover at least a portion of the upper protective layer 115 and may extend into the second upper opening HU2. The upper pattern 150B may fill at least a portion of the second upper opening HU2, and the upper surface of the metal layer 150M of the upper pattern 150B may be in contact with the underfill portion UF. When the semiconductor package 100B includes upper openings HU and second upper openings HU2, the upper openings HU may be central openings (or upper central openings) and the second upper openings HU2 may be outer openings (or upper outer openings). As an example, a depth of each of the outer openings HU2 may be greater than a depth of the corresponding central opening HU surrounded by the outer opening HU2.

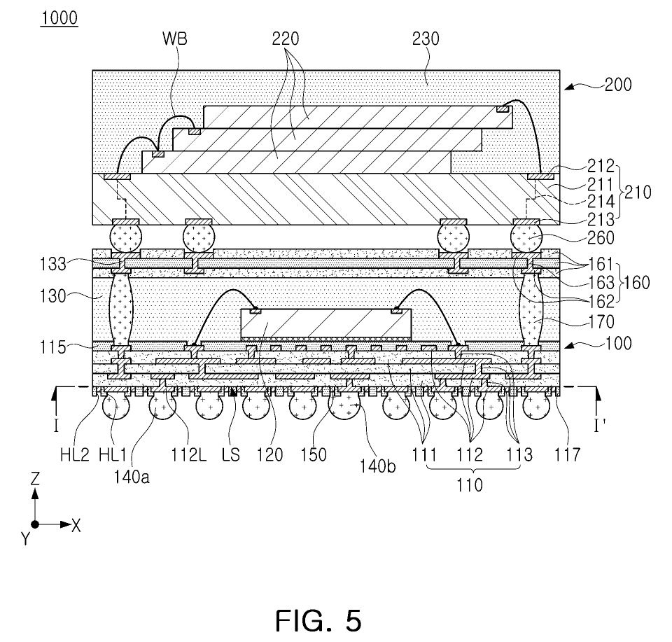

FIG. 5 is a cross-sectional view illustrating a semiconductor package 1000 according to an embodiment of the present inventive concept.

Referring to FIG. 5, the semiconductor package 1000 of an embodiment may include a first package 100 and a second package 200. The first package 100 may be redisposed/replaced with the semiconductor packages 100, 100A, and 100B described above with reference to FIGS. 1 to 4 or semiconductor packages having similar characteristics, except that the first package 100 further includes a conductive post 170 and an upper interconnection structure 160.

The conductive post 170 may electrically connect the substrate 110 and the upper interconnection structure 160 by penetrating the encapsulant 130. The conductive post 170 may include at least one of copper (Cu) and a copper (Cu) alloy. A seed layer (not illustrated) may be disposed below the conductive post 170. The seed layer (not illustrated) may include at least one of titanium (Ti), a titanium (Ti) alloy, copper (Cu), and a copper (Cu) alloy.

The upper interconnection structure 160 may include an insulating member (an upper insulating layer) 161 and an upper interconnection layer 162 disposed in the upper insulating layer 161. The insulating member 161 may include a thermosetting resin, such as an epoxy resin, a thermoplastic resin, such as polyimide, or a photosensitive resin, such as ABF, FR-4, BT, or PID obtained by impregnating an inorganic filler with the thermosetting resin or the thermoplastic resin. The interconnection layers 162 may include a metal material including, for example, copper (Cu), aluminum (Al), silver (Ag), tin (Sn), gold (Au), nickel (Ni), lead (Pb), titanium (Ti), or alloys thereof. An interconnection via 163 may electrically connect the interconnection layers 162 located on different levels.

The second package 200 may include a redistribution substrate 210, a second semiconductor chip 220, and a second encapsulant 230. The redistribution substrate 210 may include a redistribution pad 213 and an upper pad 212 respectively formed on lower and upper surfaces thereof and electrically connected to the outside of the second package 200. In addition, the redistribution substrate 210 may include a redistribution circuit 214 electrically connecting the redistribution pad 213 and the upper pad 212. The second package 200 may be referred to as an upper package.

A plurality of second semiconductor chips 220 may be mounted on the redistribution substrate 210 by wire bonding or flip chip bonding. For example, the plurality of second semiconductor chips 220 may be stacked vertically on the redistribution substrate 210 and electrically connected to the upper pad 212 of the redistribution substrate 210 by bonding wires WB. In an example, the second semiconductor chip 220 may include a memory chip, and the first semiconductor chip 120 may include an AP chip.

The second encapsulant 230 may include a material identical to or similar to that of the encapsulant 130 of the first package 100. The second package 200 may be physically and electrically connected to the first package 100 by a conductive bump 260. The conductive bump 260 may be electrically connected to the redistribution circuit 214 inside the redistribution substrate 210 through the redistribution pad 213 of the redistribution substrate 210. The conductive bump 260 may include a low-melting point metal, for example, tin (Sn) or an alloy including tin (Sn).

FIGS. 6A to 6G are cross-sectional views schematically illustrating a process of manufacturing a semiconductor package 100 according to an embodiment of the present inventive concept.

Referring to FIG. 6A, a preliminary substrate 110’ on which the upper protective layer 115 and a lower protective layer 117 are formed may be prepared.

The preliminary substrate 110’ may include components/divisions for a plurality of substrates 110 separated by a sawing line SL, for example, the insulating layer 111, the interconnection layer 112, and the interconnection via 113. The insulating layer 111 may be formed by applying and curing a prepreg or a photosensitive resin. The interconnection layer 112 and the interconnection via 113 may be formed on the insulating layer 111 using a photolithography process, a plating process, an etching process, or the like.

The upper protective layer 115 may be formed by applying or attaching an insulating material (for example, solder resist ink or a film) to the upper surface US of the preliminary substrate 110’ and performing an exposure process and a development process. The lower protective layer 117 may be formed on the lower surface LS of the preliminary substrate 110’ by performing a process the same as or similar to that of the upper protective layer 115.

Referring to FIG. 6B, an upper opening HU may be formed in the upper protective layer 115, and the lower openings HL may be formed in the lower protective layer.

The upper opening HU exposing at least a portion of the upper pad 112U may be formed in the upper protective layer 115, and the first lower opening HL1 exposing at least a portion of the lower pad 112L may be formed in the lower protective layer 117. The width of the first lower opening HL1 in the horizontal direction (e.g., in the X or Y-axis direction) may be smaller than the width of the lower pad 112L in the horizontal direction, and the width of the upper opening HU in the horizontal direction (e.g., in the X or Y-axis direction) may be smaller than the width of the upper pad 112U in the horizontal direction, but the widths are not limited thereto. The second lower opening HL2 may be formed along the circumference of the first lower opening HL1.

Referring to FIG. 6C, the lower pattern 150A filling the second opening HL2 may be formed.

The lower pattern 150A may include the seed layer 150S and the metal layer 150M formed on the seed layer 150S, and the lower pattern 150A may be formed through a plating process. The thickness of the lower pattern 150A may be the same as the thickness of the lower pad 112L, but is not limited thereto, and the lower pattern 150A may be formed thinner or thicker than the lower pad 112L.

Referring to FIG. 6D, the semiconductor chip 120 may be mounted on the preliminary substrate 110’.

The semiconductor chip 120 may be disposed on an upper protective layer 115 and may be attached to the upper protective layer 115 through the adhesive layer 125 disposed below the semiconductor chip 120. The connection pads 121 of the semiconductor chip 120 may be electrically connected to the upper pads 112U on the upper surface US of the preliminary substrate 110’ through the conductive wire CW. The semiconductor chip 120 may have a front surface on which connection pads 121 are disposed and a rear surface located opposite to the front surface and may be disposed such that the rear surface of the semiconductor chip 120 is located on and/or faces an upper protective layer 115. The semiconductor chip 120 may be disposed on the first upper protective layer 115 such that the front surface FS on which the connection pads 121 are arranged faces upward. The semiconductor chip 120 may be attached to the first upper protective layer 115 by an adhesive layer 125 (e.g., a double-sided film (DF) or a dichroic film (DF)). Next, the conductive wire CW electrically connecting the connection pads 121 to the interconnection layer 112 may be formed. The conductive wire CW may be formed by a wire bonding process using a capillary. The conductive wire CW may include gold (Au), silver (Ag), lead (Pb), aluminum (Al), copper (Cu), or alloys thereof.

Referring to FIG. 6E, the encapsulant 130 may be formed. The encapsulant 130 may be formed to cover the semiconductor chip 120 and the upper protective layer 115. The encapsulant 130 may be formed by applying and curing an insulating resin, such as EMC. According to an embodiment, a planarization process may be applied to the upper surface of the encapsulant 130.

Referring to FIG. 6F, a preliminary connection bump 140p may be disposed. The preliminary connection bump 140p may be aligned on the lower pad 112L disposed on the lower surface LS of the preliminary substrate 110’. Before disposing the preliminary connection bump 140p, the flux FLX may be applied to the location in which the preliminary connection bump 140p is to be disposed. The flux FLX may perform a role of removing an oxide film on the surface of the lower pad 112L and may perform a role of aligning the preliminary connection bump 140p, e.g., on the lower pad 112L. According to an embodiment, the flux may extend into the second lower opening HL2 disposed around the first lower opening HL1 in which the lower pad 112L is exposed (see ‘B’ of FIG. 6F).

Referring to FIG. 6G, the connection bump 140 may be formed through a reflow process. The preliminary connection bump (140p, see FIG. 6F) may extend or expand to a region in which the flux (FLX, see FIG. 6F) applied in the previous process is located as high temperature is applied to the preliminary connection bump 140p. As the reflow process is performed, the flux FLX may be removed and the connection bump 140 may be formed. Some of the connection bumps 140 may fill the second lower opening HL2 and may be in contact with the lower pattern 150A, according to an embodiment.

Referring to FIG. 1, thereafter, the encapsulant 130, the first upper protective layer 115, the lower protective layer 117, and the preliminary substrate 110’ may be cut along the sawing line SL to separate the individual semiconductor packages 100.

According to embodiments of the present inventive concept, by introducing the opening that horizontally surrounds the connection bump and the lower pad in contact therewith and a sacrificial pad filling the opening, the semiconductor package with improved reliability may be provided.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While embodiments have been illustrated and described above, it will be apparent to those skilled in the art that modifications and variations could be made without departing from the scope of the present invention as defined by the appended claims.

What is claimed is:

1. A semiconductor package comprising:
a substrate including an insulating layer and an interconnection layer disposed on the insulating layer, the interconnection layer formed of conductive patterns, the substrate having a lower surface on which lower pads are disposed and an upper surface on which upper pads are disposed;
an upper protective layer disposed on the upper surface of the substrate and having upper openings exposing respective portions of the upper pads;
a lower protective layer disposed on the lower surface of the substrate and having lower openings exposing respective portions of the lower pads;
a semiconductor chip disposed on the upper protective layer and including connection pads electrically connected to at least a portion of the upper pads through the upper openings;
an encapsulant covering at least a portion of each of the upper protective layer and the semiconductor chip on the upper protective layer; and
connection bumps disposed below the lower protective layer,
wherein
the lower openings include first lower openings and second lower openings surrounding at least a portion of each of the first lower openings,
the lower pads are respectively disposed within the first lower openings and lower patterns are respectively disposed within the second lower openings, and
the connection bumps are electrically connected to the lower pads within the first lower openings, respectively.

2. The semiconductor package of claim 1, wherein the lower patterns are electrically insulated from the interconnection layer.

3. The semiconductor package of claim 1, wherein the lower patterns include a seed layer and a metal layer on the seed layer.

4. The semiconductor package of claim 1, wherein the lower patterns include the same material as that of the lower pads.

5. The semiconductor package of claim 1, wherein at least a portion of the connection bumps fills an inside of the second lower openings and contacts at least a portion of the lower patterns.

6. The semiconductor package of claim 1, wherein the second lower openings include a plurality of divided portions.

7. The semiconductor package of claim 6, wherein the second lower openings are disposed between two adjacent first lower openings among the first lower openings.

8. The semiconductor package of claim 1, wherein the second lower openings are ring-shaped, surrounding the first lower openings, in a plan view.

9. The semiconductor package of claim 1, wherein an upper surface of each lower pattern is located on a lower level than an upper surface of a corresponding lower pad.

10. The semiconductor package of claim 1, wherein the upper protective layer has a central opening exposing at least a portion of the upper pads and an outer opening surrounding at least a portion of a circumference of the central opening.

11. The semiconductor package of claim 1, further comprising:
conductive bumps electrically connecting the connection pads of the semiconductor chip and at least a portion of the upper pads below the semiconductor chip; and
an underfill portion surrounding at least a portion of each of the conductive bumps and filling at least a portion of an inside of an outer opening below the semiconductor chip.

12. The semiconductor package of claim 1, further comprising:
an upper interconnection structure disposed on the encapsulant and including an upper insulating layer and an upper interconnection layer disposed within the upper insulating layer;
a conductive post penetrating the encapsulant in a vertical direction on the substrate and electrically connecting the substrate and the upper interconnection structure; and
an upper package disposed on the upper interconnection structure and electrically connected to the upper interconnection structure.

13. The semiconductor package of claim 1, further comprising:
an adhesive layer attaching the semiconductor chip to the substrate below the semiconductor chip; and
a conductive wire electrically connecting one of the connection pads of the semiconductor chip and one of the upper pads of the substrate.

14. The semiconductor package of claim 1, wherein a horizontal width of each second lower opening is smaller than a horizontal width of a corresponding first lower opening.

15. A semiconductor package comprising:
a substrate including an insulating layer and an interconnection layer, disposed on the insulating layer, and having a lower surface on which a lower pad is disposed and an upper surface on which an upper pad is disposed;
a lower protective layer covering a portion of the lower pad below the lower surface of the substrate;
an upper protective layer covering a portion of the upper pad on the upper surface of the substrate;
a semiconductor chip disposed on the substrate and electrically connected to at least a portion of the upper pad through central openings;
an encapsulant encapsulating at least a portion of the semiconductor chip on the substrate; and
connection bumps electrically connected to the lower pad below the lower protective layer,
wherein at least one of the upper protective layer and the lower protective layer includes central openings exposing at least a portion of the upper pad or the lower pad and outer openings surrounding at least a portion of a circumference of each of the central openings.

16. The semiconductor package of claim 15, further comprising dummy patterns filling the outer openings, respectively.

17. The semiconductor package of claim 15, wherein a depth of each of the outer openings is greater than a depth of a corresponding one of the central openings adjacent to the outer opening.

18. The semiconductor package of claim 15, wherein a horizontal width of each of the outer openings is smaller than a horizontal width of each of the central openings.

19. A semiconductor package comprising:
a substrate including an insulating layer and an interconnection layer disposed on the insulating layer, the substrate having a lower surface on which a lower pad is disposed;
a lower protective layer covering a portion of the lower pad and a portion of the lower surface of the substrate;
a semiconductor chip disposed on the substrate and electrically connected to the interconnection layer;
an encapsulant encapsulating the semiconductor chip on the substrate; and
connection bumps electrically connected to the lower pad, the connection bumps overlapping the lower protective layer in a horizontal direction,
wherein the lower protective layer has a plurality of first openings and a plurality of second openings respectively surrounding at least portions of the plurality of first openings,
each of the plurality of first openings forms a group with at least one second opening adjacent to the corresponding first opening to form a plurality of groups of openings, and
a gap between a first opening and a second opening in a first group among the plurality of groups is smaller than a gap between the second opening in the first group and a second opening in a second group among the plurality of groups.

20. The semiconductor package of claim 19, further comprising a lower pattern filling the second opening and electrically insulated from the interconnection layer.
